(19) United States
(12) Patent Application Publication
(10) Pub. No.: US 2020/0006659 A1
(43) Pub. Date: Jan. 2, 2020

(54) DEPOSITION APPARATUS AND METHOD OF ALIGNING MAGNET PLATE OF DEPOSITION APPARATUS

(71) Applicant: Samsung Display Co., Ltd., Yongin-si (KR)

(72) Inventor: Junghyun AHN, Seongnam-si (KR)

(21) Appl. No.: 16/380,946

(22) Filed: Apr. 10, 2019

(30) Foreign Application Priority Data
Jun. 29, 2018 (KR) 10-2018-0075545

(51) Int. Cl. H01L 51/00; H01L 51/56; C23C 14/04; C23C 14/50; B25B 11/00

(52) U.S. Cl. CPC H01L 51/0012; H01L 51/001; H01L 51/0011; B25B 11/002; C23C 14/042; C23C 14/50; H01L 51/56

(57) ABSTRACT

A deposition apparatus including a driving unit configured to be movable in first and second directions crossing each other and to be rotatable about a rotation axis parallel to a third direction normal to a plane defined by the first and second directions, a first supporting member connected to a bottom end of the driving unit in the third direction, a magnet plate disposed below and connected to the first supporting member, a second supporting member disposed below the magnet plate, and a plurality of first connection units disposed on the first supporting member. The first connection units may extend in the third direction, may penetrate the first supporting member and the magnet plate, and may be connected to the second supporting member.

### CROSS-REFERENCE TO RELATED APPLICATION

This application claims priority from and the benefit of Korean Patent Application No. 10-2018-0075545, filed on Jun. 29, 2018, which is hereby incorporated by reference for all purposes as if fully set forth herein.

### BACKGROUND

### Field

Exemplary embodiments of the invention relate generally to a deposition apparatus and a method of aligning a magnet plate of a deposition apparatus, and more specifically, to a deposition apparatus, which is configured to easily align a magnet plate to a mask, and a method of aligning a magnet plate of a deposition apparatus.

### Disscussion of the Background

An organic light emitting diode (OLED) display device has been attracting attention as a next generation flat panel display device, because it provides excellent luminance and viewing angle characteristics without a light source unit necessarily required for a liquid crystal display (LCD) device. Since there is no need for the light source unit, the OLED display device can be fabricated to be lighter and thinner than the LCD device. In addition, the OLED display device has other technical advantages (e.g., low power consumption, high luminance, and high response speed).

The OLED display device includes a plurality of organic light emitting devices, each of which includes an anode, an organic light emitting layer, and a cathode. If holes and electrons are injected from the anode and the cathode, respectively, into the organic light emitting layer, excitons are formed in the organic light emitting layer. When the excitons undergo a transition to the ground state, light is emitted from the organic light emitting device.

A process of fabricating the organic light emitting devices includes placing a mask on a substrate and providing an organic material, which is used to form the organic light emitting layers, onto the substrate through openings of the mask. Since the mask is a metal-containing thin structure, it is difficult to maintain flatness of the mask to a high level. Various tools, such as a fastening frame and a magnet plate, are used to maintain a flat shape of the mask, when the mask is adhered to the substrate.

However, in the case where the mask is repeatedly used to process a plurality of substrates, there may be a difficulty in aligning the mask to the magnet plate. For example, the mask may be misaligned or misplaced from the magnet plate. In this case, it is difficult to maintain the flatness of the mask on the substrate to a desired level.

The above information disclosed in this Background section is only for understanding of the background of the inventive concepts, and, therefore, it may contain information that does not constitute prior art.

### SUMMARY

Exemplary embodiments of the invention provide a deposition apparatus, which is configured to easily align a magnet plate to a mask, and a method of aligning a magnet plate of a deposition apparatus.

Additional features of the inventive concepts will be set forth in the description which follows, and in part will be apparent from the description, or may be learned by practice of the inventive concepts.

An exemplary embodiment of the invention provides a deposition apparatus including a driving unit configured to be movable in first and second directions crossing each other and to be rotatable about a rotation axis parallel to a third direction normal to a plane defined by the first and second directions; a first supporting member connected to a bottom end of the driving unit in the third direction; a magnet plate disposed below and connected to the first supporting member; a second supporting member disposed below the magnet plate; and a plurality of first connection units disposed on the first supporting member. The first connection units extends in the third direction, penetrates the first supporting member and the magnet plate, and is connected to the second supporting member.

Another exemplary embodiment of the invention provides a method of aligning a magnet plate of a deposition apparatus including preparing a driving unit, a first supporting member connected to a bottom end of the driving unit, a magnet plate disposed below and is connected to the first supporting member, and a second supporting member disposed below the magnet plate; providing a mask below the second supporting member and a substrate on the mask; aligning the substrate to the mask; moving the magnet plate using the driving unit to align the magnet plate to the mask; moving the second supporting member in a downward direction to be in contact with the substrate; and moving the magnet plate to a position adjacent to the second supporting member to allow the mask to be in contact with the substrate. The driving unit is movable in first and second directions crossing each other and rotatable about a rotation axis parallel to a third direction normal to a plane defined by the first and second directions.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the inventive concepts.

FIG. 1 is a perspective view illustrating a deposition apparatus according to an exemplary embodiment of the invention.

FIG. 2 is a plan view illustrating a first supporting member, on which first connection units shown in FIG. 1 are provided.

FIG. 3 is a bottom plan view of a third supporting member shown in FIG. 1.

FIG. 4 is a sectional view illustrating an example of a third supporting member, in is which a recessed region shown in FIG. 3 is defined.

FIG. 5 is a diagram illustrating an example of a structure of a driving unit disposed in a third supporting member shown in FIG. 3.

FIG. 6 is a side view of a deposition apparatus of FIG. 1 viewed from a second direction.

FIG. 7 is a sectional view illustrating one of first connection units shown in FIG. 6.

FIG. 8, FIG. 9, FIG. 10, FIG. 11, and FIG. 12 are diagrams illustrating an operation of aligning a magnet plate of the deposition apparatus shown in FIG. 6.

### DETAILED DESCRIPTION

In the following description, for the purposes of explanation, numerous specific details are set forth in order to provide a thorough understanding of various exemplary embodiments of the invention. As used herein “embodiments” are non-limiting examples of devices or methods employing one or more of the inventive concepts disclosed herein. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be is understood as providing exemplary features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an exemplary embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used is herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

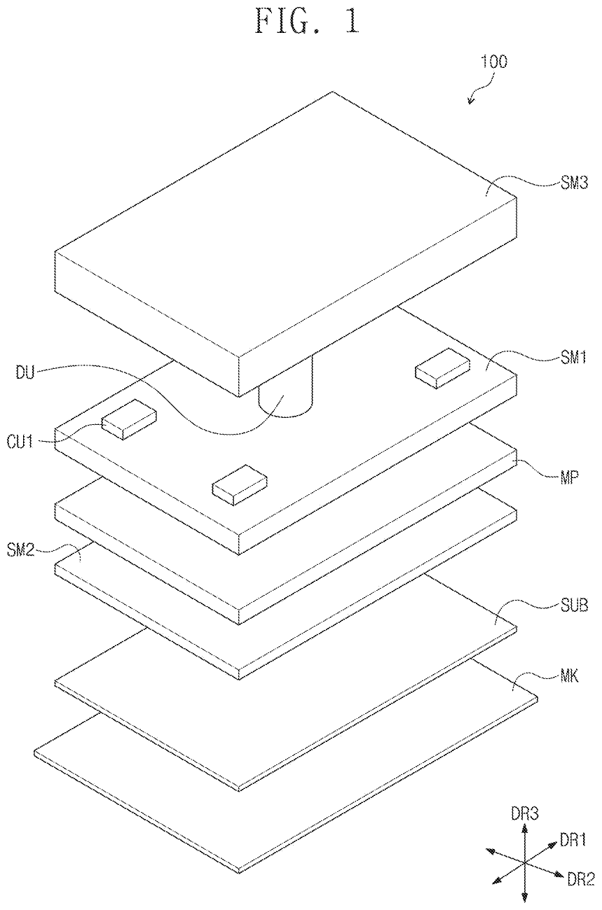

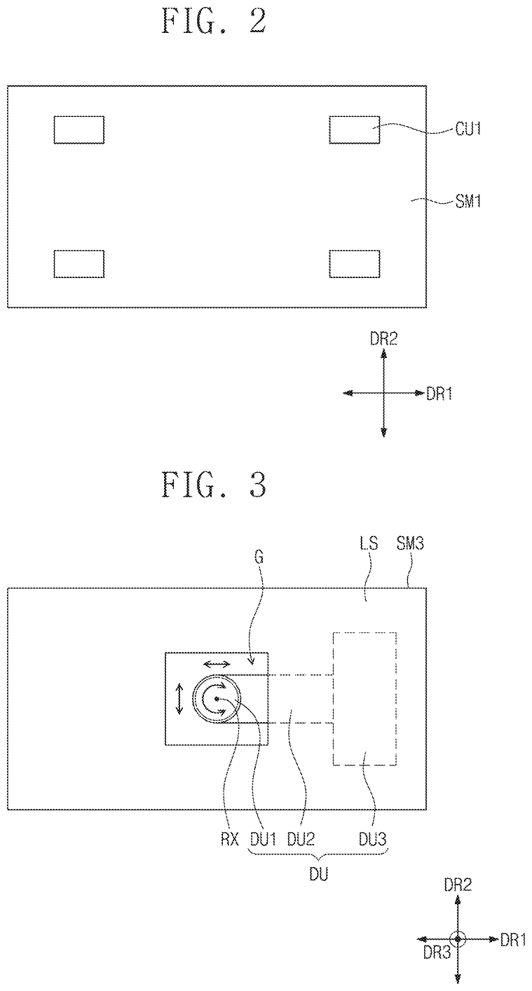

FIG. 1 is a perspective view illustrating a deposition apparatus according to an exemplary embodiment of the inventive concepts. FIG. 2 is a plan view illustrating a first supporting member, on which first connection units shown in FIG. 1 are disposed.

Referring to FIGS. 1 and 2, a deposition apparatus 100 may include a first supporting member SM1, a second supporting member SM2, a third supporting member SM3, a driving unit DU, a magnet plate MP, and a plurality of first connection units CU1.

Each of the first, second, and third supporting members SM1, SM2, and SM3 and the magnet plate MP may have a rectangular shape whose long sides extend parallel to a first direction DR1 and whose short sides extend parallel to a second direction DR2 crossing the first direction DR1.

Hereinafter, a direction perpendicular to both of the first and second directions DR1 and DR2 will be referred to as a third direction DR3. Each of the first, second, and third directions DR1, DR2, and DR3 may be defined in a bidirectional manner.

The first supporting member SM1 may be connected to a bottom end of the driving unit DU. The magnet plate MP may be placed below the first supporting member SM1.

The second supporting member SM2 may be placed below the magnet plate MP. Thus, the magnet plate MP may be disposed between the first supporting member SM1 and the second supporting member SM2. The magnet plate MP may be formed of, or to include, a magnetic material.

The driving unit DU may be connected to the first supporting member SM1. When measured in the third direction DR3, a thickness of the first supporting member SM1 may be greater than a thickness of each of the magnet plate MP and the second supporting member SM2. When measured in the third direction DR3, a thickness of the third supporting member SM3 may be greater than the thickness of the first supporting member SM1.

The first connection units CU1 may be placed on the first supporting member SM1. The first connection units CU1 may be disposed to extend in the third direction DR3 and to penetrate the first supporting member SM1 and the magnet plate MP and thereby may be connected to the second supporting member SM2. This will be described in more detail below.

In an exemplary embodiment, as shown in FIG. 2, four first connection units CU1 may be disposed on the first supporting member SM1. However, the inventive concepts are not limited to this example, and at least two first connection units CU1 may be disposed on the first supporting member SM1. The first connection units CU1 may be disposed near respective corners of the first supporting member SM1.

A substrate SUB and a mask MK may be placed below the second supporting member SM2. Each of the substrate SUB and the mask MK may have a rectangular shape whose long sides extend parallel to a first direction DR1 and whose short sides extend parallel to the second direction DR2. The substrate SUB may be used as a substrate for a deposition process and may be an organic substrate or a plastic substrate. In an exemplary embodiment, the mask MK may be a metal-containing fine metal mask (FMM).

Although not shown, a crucible, in which a deposition material is stored, may be placed below the mask MK. If the crucible is heated to evaporate the deposition material, the evaporated deposition material may be provided onto the substrate SUB through the openings of the mask MK.

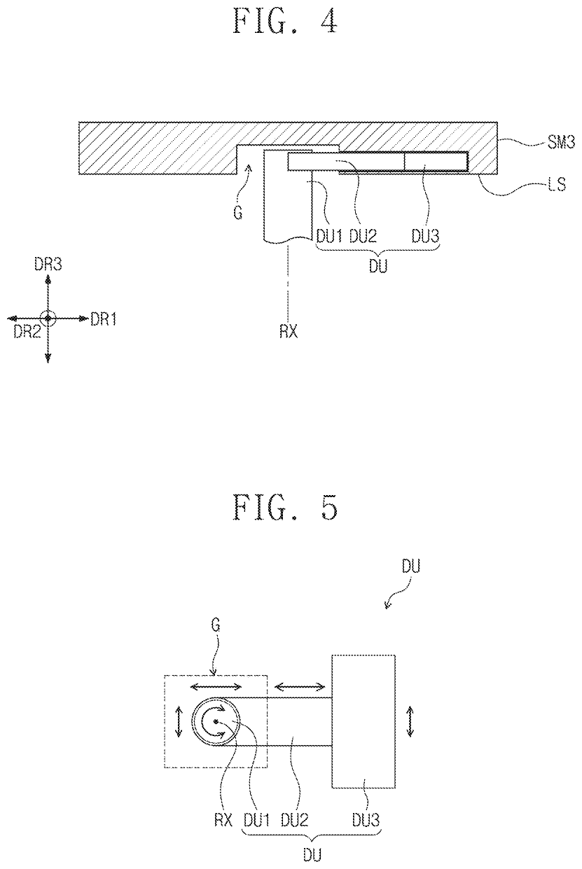

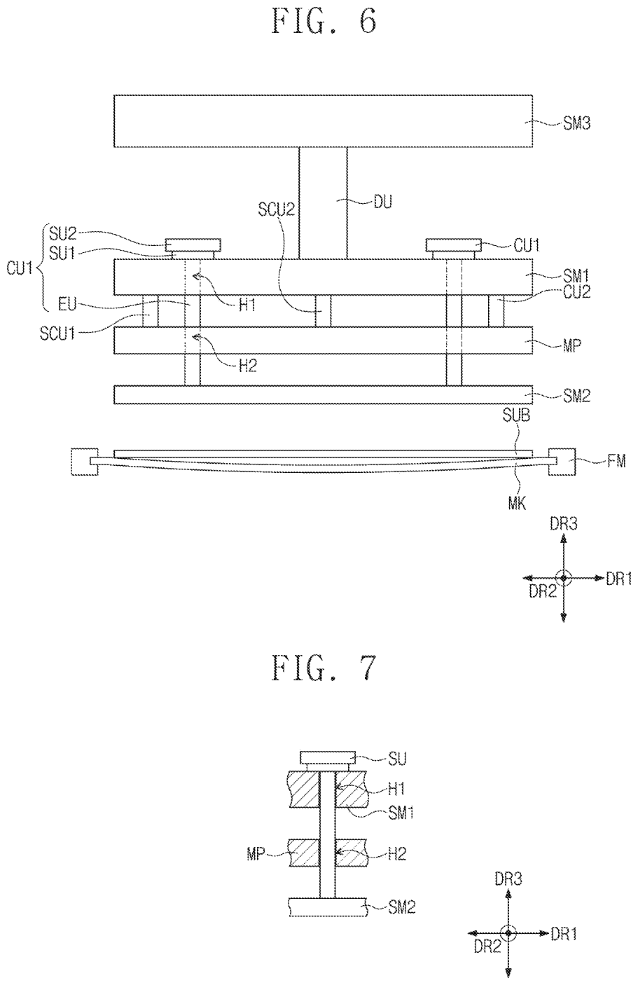

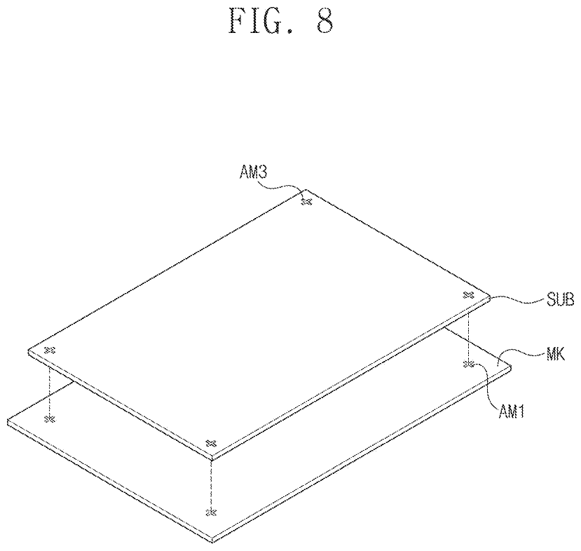

FIG. 3 is a bottom plan view of a third supporting member shown in FIG. 1. FIG. 4 is a sectional view illustrating an example of a third supporting member, in which a recessed region shown in FIG. 3 is defined. FIG. 5 is a diagram illustrating an example of a structure of a driving unit disposed in a third supporting member shown in FIG. 3.

FIG. 5 illustrates positions of first, second, and third driving units DU1, DU2, and DU3 relative to a recessed region G (e.g., depicted by a dotted line), but for convenience in illustration, the third supporting member SM3 is omitted from FIG. 5.

Referring to FIGS. 3, 4, and 5, the driving unit DU may be connected to the third supporting member SM3. The recessed region G may be defined in a center region of a bottom surface LS of the third supporting member SM3, and the driving unit DU may be exposed through the recessed region G. The recessed region G may be a region, which is recessed from the bottom surface LS of the third supporting member SM3 toward an inner portion of the third supporting member SM3. The recessed region G may have a rectangular shape, but the inventive concept is not limited to a specific shape of the recessed region G.

The driving unit DU may include a first driving unit DU1, a second driving unit DU2, and a third driving unit DU3. The first driving unit DU1 may be configured to extend in the third direction DR3 and to be rotatable about a rotation axis RX parallel to the third direction DR3. The first driving unit DU1 may be configured to rotate clockwise or counterclockwise about the rotation axis RX. Below the first supporting member SM1, the first driving unit DU1 may be exposed to the outside through the recessed region G.

The second driving unit DU2 may be connected to the first driving unit DU1 and may extend in the first direction DR1. A portion of the second driving unit DU2 connected to the first driving unit DU1 may be exposed through the recessed region G, and other portions of the second driving unit DU2 may be placed in the third supporting member SM3. The second driving unit DU2 may be configured to be movable in the first direction DR1.

The third driving unit DU3 may be connected to the second driving unit DU2 and may extend in the second direction DR2. The second driving unit DU2 may be placed between the first driving unit DU1 and the third driving unit DU3, and an end portion of the second driving unit DU2 may be connected to a center region of the third driving unit DU3. The third driving unit DU3 may be placed in the third supporting member SM3. The third driving unit DU3 may be configured to be movable in the second direction DR2.

Since the second driving unit DU2 connected to the first driving unit DU1 is movable in the first direction DR1, the first driving unit DU1 may be moved in the first direction DR1 by the second driving unit DU2. Since the first driving unit DU1 is connected to the second driving unit DU2, the second driving unit DU2 is connected to the third driving unit DU3, and the third driving unit DU3 is movable in the second direction DR2, the first driving unit DU1 may be moved in the second direction DR2 by the third driving unit DU3.

Thus, as a result of the use of the second and third driving units DU2 and DU3, the first driving unit DU1 may be allowed to move in both of the first and second directions DR1 and DR2. The first driving unit DU1 may move in the first and second directions DR1 and DR2, within the recessed region G.

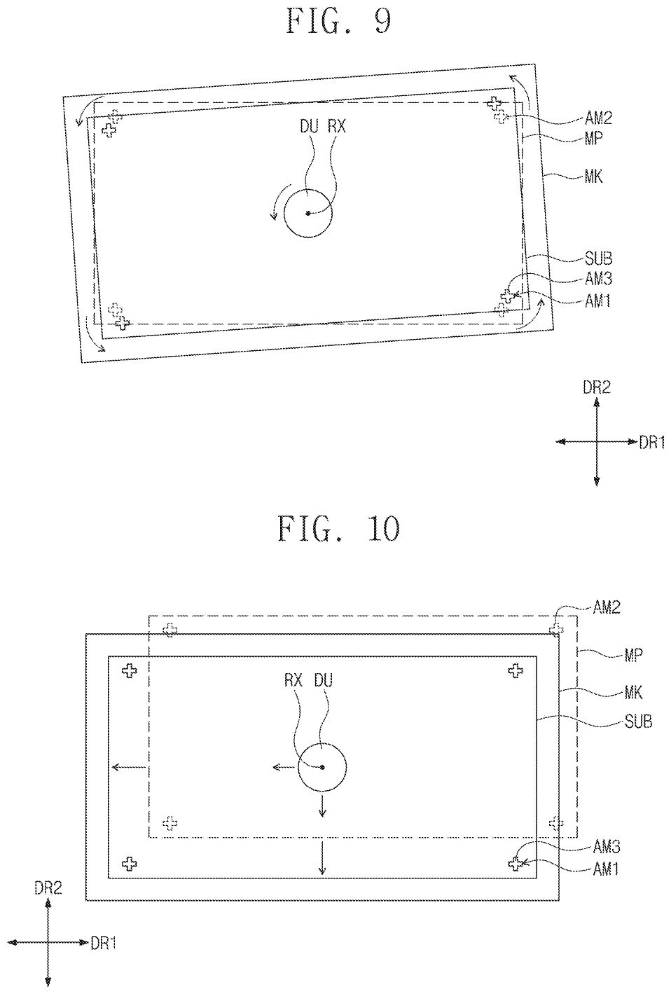

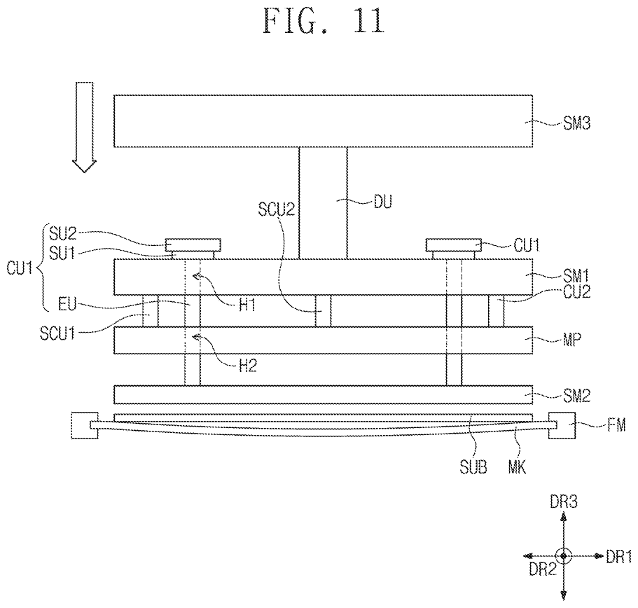

FIG. 6 is a side view of a deposition apparatus of FIG. 1 viewed in a second direction. FIG. 7 is a sectional view illustrating one of first connection units shown in FIG. 6.

Referring to FIGS. 6 and 7, the first connection units CU1 may be disposed on the first supporting member SM1. The first connection units CU1 may be disposed to extend in the third direction DR3 and to penetrate the first supporting member SM1 and the magnet plate MP and, thereby, may be connected to the second supporting member SM2.

The first connection units CU1 extending in the third direction DR3 may be connected to the second supporting member SM2 through a plurality of first holes H1 defined in the first supporting member SM1 and a plurality of second holes H2 defined in the magnet plate MP. The first holes H1 may be overlapped with the second holes H2, respectively. In FIG. 6, for convenience in illustration, the first and second holes H1 and H2 are depicted by dotted lines.

Each of the first connection units CU1 may include a first support unit SU1, a second support unit SU2, and an extended unit EU. The first support unit SU1 may be disposed on the first supporting member SM1 and may have an area larger than that of each of the first and second holes H1 and H2. The area of the first support unit SU1 may be an area measured on a plane defined by the first and second directions DR1 and DR2.

The second support unit SU2 may be disposed on the first support unit SU1 and may have an area greater than that of the first support unit SU1. The area of the second support unit SU2 may also be an area measured on a plane defined by the first and second directions DR1 and DR2. In an exemplary embodiment, each of the first and second support units SU1 and SU2 may have a rectangular shape, but the inventive concepts are not limited to specific shapes of the first and second support units SU1 and SU2.

The extended unit EU may be connected to a bottom of the first support unit SU1 and may extend in the third direction DR3. The extended unit EU may be disposed to pass through the first and second holes H1 and H2 and may be connected to the second supporting member SM2. The extended unit EU may not be fastened to the first supporting member SM1 and the magnet plate MP. Thus, the first supporting member SM1 and the magnet plate MP may be moved in the third direction DR3, along with the extended unit EU.

A plurality of second connection units CU2 may be disposed between the first supporting member SM1 and the magnet plate MP. The second connection units CU2 may extend in the third direction DR3 and may connect the first supporting member SM1 to the magnet plate MP. For example, a top end of each of the second connection units CU2 may be connected to the first supporting member SM1, and a bottom end of each of the second connection units CU2 may be connected to the magnet plate MP.

The second connection units CU2 may include a plurality of first sub-connection units SCU1, which are disposed adjacent to an edge of the first supporting member SM1 and an edge of the magnet plate MP, and a second sub-connection unit SCU2, which is disposed near a center region of the first supporting member SM1 and a center region of the magnet plate MP. The second sub-connection unit SCU2 may be omitted.

The driving unit DU may be connected to the first supporting member SM1, and the first supporting member SM1 may be connected to the magnet plate MP through the second connection units CU2. Thus, when the driving unit DU moves in the first and second directions DR1 and DR2 and rotates about the rotation axis RX, the first supporting member SM1 and the magnet plate MP may move in the first and second directions DR1 and DR2 and may rotate about the rotation axis RX.

In an exemplary embodiment, the first sub-connection units SCU1 may closer to the edge of the first supporting member SM1 than the first connection units CU1. However, the inventive concepts are not limited to this example, and the first connection units CU1 may be closer to the edge of the first supporting member SM1 than the first sub-connection units SCU1.

The substrate SUB may be disposed on the mask MK, and an edge of the mask MK may be connected to a fastening frame FM. Since the mask MK is fabricated to have a very small thickness, it may be difficult to maintain a high degree of flatness of the mask MK. For example, the mask MK may be in a drooping state, as shown in FIG. 6.

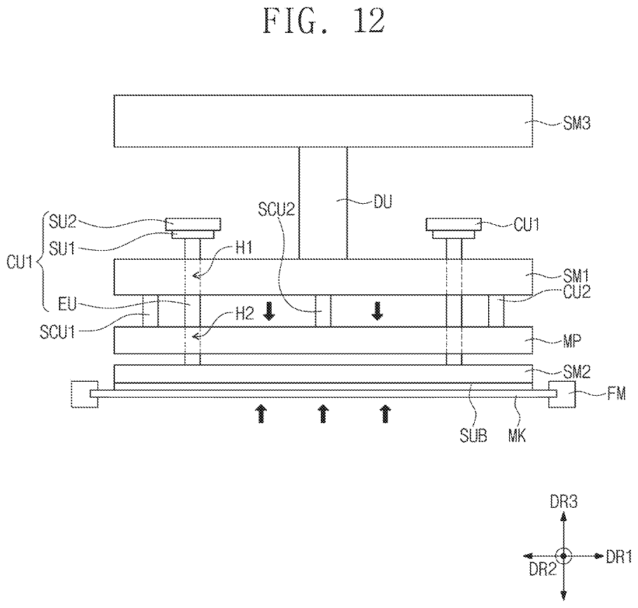

FIGS. 8 to 12 are diagrams illustrating an operation of aligning a magnet plate of the deposition apparatus shown in FIG. 6.

By changing a position or a direction of the driving unit DU, it may be possible to control a position or direction of the magnet plate MP, and this will be described in more detail with reference to FIGS. 8 to 10. FIGS. 11 and 12 illustrate an operation of the magnet plate MP for moving the mask MK in a downward direction.

Referring to FIGS. 8 to 10, the mask MK may include a plurality of first alignment marks AM1 disposed in predetermined regions of the mask MK. For example, the first alignment marks AM1 may be disposed near respective corners of the mask MK.

The magnet plate MP may include a plurality of second alignment marks AM2 disposed in predetermined regions of the magnet plate MP. For example, the second alignment marks AM2 may be disposed near respective corners of the magnet plate MP.

The substrate SUB may include a plurality of third alignment marks AM3 disposed in predetermined regions of the substrate SUB. For example, the third alignment marks AM3 may be disposed near respective corners of the substrate SUB.

For convenience in illustration, the magnet plate MP and the second alignment marks AM2 are depicted by the dotted line in FIGS. 9 and 10. Each of the first, second, and third alignment marks AM1, AM2, and AM3 is illustrated to have a cross shape, but the inventive concept is not limited to this example. For example, the shapes of the first, second, and third alignment marks AM1, AM2, and AM3 may be variously changed.

Referring to FIG. 8, the substrate SUB may be disposed on the mask MK, and then, the substrate SUB may be aligned to the mask MK in such a way that the third alignment marks AM3 of the substrate SUB are placed at positions overlapped with the first alignment marks AM1 of the mask MK.

Referring to FIG. 9, the mask MK may be misaligned to the magnet plate MP. For example, a center of the mask MK may be aligned to a center of the magnet plate MP, but the mask MK may be rotated counterclockwise from the magnet plate MP by a specific angle.

The driving unit DU may be driven to move the magnet plate MP. For example, the driving unit DU may rotate the magnet plate MP. As shown in FIG. 9, when the mask MK is rotated from the magnet plate MP, the driving unit DU may rotate the magnet plate MP in a counterclockwise direction to move the magnet plate MP. For example, in the case where the first driving unit DU1 of the driving unit DU is rotated in the counterclockwise direction, the magnet plate MP may be rotated in the counterclockwise direction.

The driving unit DU may move the magnet plate MP in such a way that the second alignment marks AM2 of the magnet plate MP are located at positions overlapped with the first and third alignment marks AM1 and AM3 overlapped with each other. In this case, the magnet plate MP may be precisely aligned to the mask MK and the substrate SUB.

Although not shown, in the case where the mask MK is rotated clockwise from the magnet plate MP by a specific angle, the driving unit DU may rotate clockwise the magnet plate MP about the rotation axis RX to allow the second alignment marks AM2 to be overlapped with the first and third alignment marks AM1 and AM3.

Referring to FIG. 10, the mask MK may be misplaced from the magnet plate MP by specific distances in the first and second directions DR1 and DR2. The driving unit DU may move the magnet plate MP in the first and second directions DR1 and DR2.

The second driving unit DU2 of the driving unit DU may be moved in the first direction DR1 to move the magnet plate MP in the first direction DR1. The third driving unit DU3 of the driving unit DU may be moved in the second direction DR2 to move the magnet plate MP in the second direction DR2.

The driving unit DU may move the magnet plate MP in such a way that the second alignment marks AM2 of the magnet plate MP are located at positions overlapped with the first and third alignment marks AM1 and AM3 overlapped with each other. In this case, the magnet plate MP may be precisely aligned to the mask MK and the substrate SUB.

In some cases, although not shown, the mask MK may be rotated clockwise from the magnet plate MP by a specific angle and may be misplaced from the magnet plate MP by specific distances in the first and second directions DR1 and DR2. In this case, the operations described with reference to FIGS. 9 and 10 may be performed. For example, the magnet plate MP may be rotated by the rotational motion of the first driving unit DU1, and the magnet plate MP may be moved in the first and second directions DR1 and DR2 by the translational motions of the second and third driving units DU2 and DU3.

In the case where the mask MK is misaligned or misplaced, the substrate SUB may be aligned to the mask MK, and then, the magnet plate MP may be aligned to the mask MK. However, the inventive concepts are not limited to this example. For example, even when the substrate SUB is not aligned to the mask MK, the magnet plate MP may be previously aligned to the mask MK, and then, the substrate SUB may be disposed on and aligned to the mask MK.

Referring to FIG. 11, the third supporting member SM3 may be configured to move in the third direction DR3. In the case where the third supporting member SM3 moves in a downward direction, the driving unit DU, the first and second supporting members SM1 and SM2, and the magnet plate MP, along with the third supporting member SM3, may also move in the downward direction.

Referring to FIG. 12, in the case where the second supporting member SM2 is moved in the downward direction, the second supporting member SM2 may be in contact with a top surface of the substrate SUB. Since the second supporting member SM2 is in contact with the substrate SUB, the substrate SUB may be supported by the second supporting member SM2.

Even when the second supporting member SM2 is in contact with the top surface of the substrate SUB, the first supporting member SM1 and the magnet plate MP may move downward along the extended unit EU inserted in the first and second holes H1 and H2. The magnet plate MP may be placed adjacent to the second supporting member SM2 through the downward motion along the extended unit EU.

Since the magnet plate MP is placed adjacent to the second supporting member SM2, a position of the magnet plate MP may be closer to the mask MK than the position shown in FIG. 7. The mask MK may be pulled up toward the magnet plate MP by a magnetic force from the magnet plate MP, thereby being in contact with a bottom surface of the substrate SUB. In other words, the mask MK may be spread to be in contact with the substrate SUB, without any drooping portion. As a result, the magnet plate MP, the substrate SUB, and the mask MK may be aligned to each other prior to a deposition process.

As described above, the magnet plate MP may be placed adjacent to the second supporting member SM2, but the position of the magnet plate MP may be variously changed. For example, in the case where it is necessary to increase a magnitude of a force for pulling the mask MK, the magnet plate MP may be moved downward to be in contact with the second supporting member SM2. In other words, the position of the magnet plate MP may be closer to the mask MK than that in FIG. 12.

By contrast, in the case where it is necessary to decrease a magnitude of a force for pulling the mask MK, the magnet plate MP may be placed at a level higher than that in FIG. 12. In other words, the position of the magnet plate MP may be farther from the mask MK than that in FIG. 12.

In the case where the mask MK is provided to have a drooping shape, openings of the mask MK may not be located on desired regions of the substrate SUB, on which a deposition material will be provided. Thus, the deposition material may not be precisely deposited on the substrate SUB. By contrast, according to an exemplary embodiment of the inventive concepts, the mask MK may have a flat spread shape and may be in contact with the substrate SUB, and thus, it may be possible to more precisely place the openings of the mask MK on the desired deposition regions of the substrate SUB. Accordingly, a deposition material may be more precisely deposited on the desired deposition regions of the substrate SUB.

If the deposition process on the substrate SUB is completed, the driving unit DU, the first and second supporting members SM1 and SM2, and the magnet plate MP may be moved upward to have the disposition shown in FIG. 7. In this case, the mask MK may again have a drooping shape. The substrate SUB may be unloaded from the mask MK, after the deposition process, a new substrate may be loaded on the mask MK, and then, the afore-described operations may be performed on the deposition apparatus provided with the new substrate.

If the deposition process is repeatedly performed on a plurality of substrates, it may be necessary to repeatedly move the magnet plate MP up and down, and in this case, the mask MK may be pulled up to repeatedly be in the drooping state. The repeated deformation of the mask MK may result in misalignment or misplacement of the mask MK.

In the case where the mask MK is misaligned or misplaced from the magnet plate MP, a portion of the mask MK which is not overlapped with the magnet plate MP may not be normally pulled up, thereby having a non-flat shape. In this case, a deposition material may not be provided on desired regions of the substrate SUB.

However, according to an exemplary embodiment of the inventive concepts, in the case where the mask MK is misaligned or misplaced, the driving unit DU may be used to move the magnet plate MP, and thus, the magnet plate MP may be easily aligned to the substrate SUB and the mask MK. Accordingly, the mask MK may be spread in a flat shape and may be in contact with the substrate SUB. As a result, it may be possible to more precisely provide a deposition material on desired regions of the substrate SUB.

According to the inventive concepts, a deposition apparatus may include a driving unit, which is configured to be movable in a first direction and a second direction and to be rotatable about a rotation axis parallel to a third direction, and is used to move a magnet plate. Accordingly, it may be possible to align the magnet plate to a mask with ease.

Although certain exemplary embodiments have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A deposition apparatus, comprising:
a driving unit configured to be movable in first and second directions crossing each other and to be rotatable about a rotation axis parallel to a third direction perpendicular to a plane defined by the first and second directions;
a first supporting member connected to a bottom end of the driving unit, in the third direction;
a magnet plate disposed below and connected to the first supporting member;
a second supporting member disposed below the magnet plate; and
a plurality of first connection units disposed on the first supporting member, the first connection units extending in the third direction, penetrating the first supporting member and the magnet plate, and being connected to the second supporting member.

2. The deposition apparatus of claim 1, wherein the first connection units are connected to the second supporting member through a plurality of first holes, which are defined in the first supporting member, and through a plurality of second holes, which are defined in the magnet plate and are overlapped with the first holes.

3. The deposition apparatus of claim 2, wherein each of the first connection units comprises:
a first support unit disposed on the first supporting member, the first support unit having an area greater than an area of each of the first and second holes, when viewed on the plane;
a second support unit disposed on the first support unit, the second support unit having an area larger than an area of the first support unit, when viewed on the plane; and
an extended unit connected to a bottom of the first support unit and extending in the third direction, the extended unit being connected to the second supporting member through the first and second holes.

4. The deposition apparatus of claim 3, wherein, when the driving unit is moved in a downward direction, the second supporting member is moved in the downward direction to be in contact with the substrate, the first supporting member and the magnet plate are moved in the downward direction along the extended unit inserted in the first and second holes, and the magnet plate is disposed adjacent to the second supporting member.

5. The deposition apparatus of claim 1, further comprising a plurality of second connection units disposed between the first supporting member and the magnet plate to connect the first supporting member to the magnet plate.

6. The deposition apparatus of claim 5, wherein the second connection units comprise:
a plurality of first sub-connection units disposed adjacent to an edge of the first supporting member and an edge of the magnet plate; and
a second sub-connection unit disposed in a center region of the first supporting member and a center region of the magnet plate.

7. The deposition apparatus of claim 6, wherein the first sub-connection units are closer to the edge of the first supporting member than the first connection units.

8. The deposition apparatus of claim 1, further comprising a third supporting member connected to a top end of the driving unit and configured to be movable in the third direction,
wherein, when measured in the third direction, a thickness of the first supporting member is greater than a thickness of each of the magnet plate and the second supporting member, and a thickness of the third supporting member is greater than the thickness of the second supporting member.

9. The deposition apparatus of claim 8, wherein the driving unit comprises:
a first driving unit rotating about the rotation axis;
a second driving unit connected to the first driving unit and moving in the first direction; and
a third driving unit connected to the second driving unit and moving in the second direction.

10. The deposition apparatus of claim 9, wherein the first driving unit is arranged in a recessed region, which is defined in a center region of a bottom surface of the third supporting member, and is movable in the first and second directions within the recessed region.

11. The deposition apparatus of claim 1, wherein the driving unit is configured to move the magnet plate in the first direction and the second direction and to rotate the magnet plate about the rotation axis, thereby aligning the magnet plate to a substrate and a mask, which are disposed below the second supporting member.

12. The deposition apparatus of claim 11, wherein:
the mask comprises a plurality of first alignment marks defined in predetermined regions of the mask;
the magnet plate comprises a plurality of second alignment marks defined in predetermined regions of the magnet plate; and
the substrate is disposed between the second supporting member and the mask and comprises a plurality of third alignment marks, which are defined in predetermined regions of the substrate and are overlapped with the second alignment marks, respectively.

13. The deposition apparatus of claim 12, wherein the driving unit is configured to move the magnet plate in the first direction and the second direction and to rotate the magnet plate about the rotation axis, thereby allowing the second alignment marks to be overlapped with the first and third alignment marks.

14. The deposition apparatus of claim 1, wherein the second supporting member comprises a metallic material.

15. The deposition apparatus of claim 1, wherein the magnet plate comprises a magnetic material.

16. A method of aligning a magnet plate of a deposition apparatus, comprising:
preparing a driving unit, a first supporting member connected to a bottom end of the driving unit, a magnet plate disposed below and connected to the first supporting member, and a second supporting member disposed below the magnet plate;
providing a mask below the second supporting member and a substrate on the mask;
aligning the substrate to the mask;
moving the magnet plate using the driving unit to align the magnet plate to the mask;
moving the second supporting member in a downward direction to be in contact with the substrate; and
moving the magnet plate to a position adjacent to the second supporting member to allow the mask to be in contact with the substrate,
wherein the driving unit is configured to be movable in first and second directions crossing each other and to be rotatable about a rotation axis parallel to a third direction perpendicular to a plane defined by the first and second directions.

17. The method of claim 16, wherein:
the mask comprises a plurality of first alignment marks defined in predetermined regions of the mask;
the magnet plate comprises a plurality of second alignment marks defined in predetermined regions of the magnet plate;
the substrate comprises a plurality of third alignment marks defined in predetermined regions of the substrate; and
the aligning of the substrate to the mask comprises placing the third alignment marks to be overlapped with the first alignment marks.

18. The method of claim 17, wherein the driving unit is configured to move the magnet plate in the first direction and the second direction and to rotate the magnet plate about the rotation axis, thereby allowing the second alignment marks to be overlapped with the first and third alignment marks.

19. The method of claim 16, wherein the driving unit comprises:
a first driving unit rotating about the rotation axis;
a second driving unit connected to the first driving unit and moving in the first direction; and
a third driving unit connected to the second driving unit and moving in the second direction.
